(19) United States
(12) Patent Application Publication
(10) Pub. No.: US 2026/0118426 A1
(43) Pub. Date: Apr. 30, 2026

(54) AI ENABLED CUSTOM DECODER GENERATION FOR TEST AND MEASUREMENT INSTRUMENTS

(71) Applicant: Tektronix, Inc., Beaverton, OR (US)

(72) Inventors: Archana I. Akkalakot, Bengaluru (IN); Akshay Gupta, Bengaluru (IN); Subhasis Bera, Bengaluru (IN); K T Anurag, Bengaluru (IN); Sushree Sangita Dash, Bengaluru (IN)

(21) Appl. No.: 19/360,366

(22) Filed: Oct. 16, 2025

(30) Foreign Application Priority Data
Oct. 24, 2024 (IN) 202421081009

(51) Int. Cl. G01R 31/319

(52) U.S. Cl. CPC G01R 31/31905; G01R 31/31912

(57) ABSTRACT

A test and measurement system, include one or more test and measurement instruments with at least one test and measurement instrument having one or more ports to connect to a device under test (DUT), one or more user interfaces, a generative artificial intelligence (AI) model connected to the one or more test and measurement instruments, and one or more processors to provide an application programming interface (API) of the generative AI model, receive a protocol specification and provide the protocol specification to the generative AI model, receive, through one of the one more user interfaces, configuration settings for a bus that operates in accordance with the protocol, provide the configuration settings to the generative AI model, receive a decoder file from the generative AI model, deploy the decoder file to the test and measurement instrument, use the decoder file on the test and measurement instrument to test a DUT.

### CROSS-REFERENCE TO RELATED APPLICATIONS

This disclosure claims priority under 35 U.S.C. § 119 to Indian Provisional Patent Application No. 202421081009, titled “AI ENABLED CUSTOM DECODER AUTOMATION,” filed on Oct. 24, 2024, the disclosure of which is incorporated herein by reference in its entirety.

### TECHNICAL FIELD

The present disclosure relates to test and measurement instruments and systems, and more particularly to the development of AI-based decoders that accelerate the extraction, generation, and deployment of protocol decoders for electronic signals.

### BACKGROUND

Serial communication is the most widely used approach to transfer data between every electronics device whether it is on computers or mobile. Protocols provide a secure and reliable form of communication adhering to a set of rules addressed by sender and receiver.

Today a lot of protocols are coming to market due to enhanced mobility, need for higher speeds of data exchange, secured data exchange, reduce power consumption in data exchange, and a need to improve the usability of data connectors.

To meet these market needs and to provide debugging solutions for the customers, a tool has been developed which helps developers to develop and release protocols as fast as possible. Tektronix test and measurement instruments support use of a Declarative Decoder Language (DDL) to develop the protocol decoders to solve the problems mentioned above. However, DDL is a proprietary language and has specific grammar and rules to which engineers need to adhere when incorporating a new protocol into test and measurement instruments.

More specifically, the existing solutions have some limitations. If the customers have their own specific protocols, it cannot be supported. The market for supporting decoders is growing faster. The Application Engineers also need to learn this grammar and develop the protocol decoder to win the competition. However, challenges are being faced in learning and then developing the decoders. The demand for custom decoders is increasing. However, deployment and maintenance of these custom solutions is tedious.

### BRIEF DESCRIPTION OF ACCOMPANYING DRAWINGS

FIG. 1 shows an embodiment of a test and measurement system.

FIG. 2 shows an embodiment of a process for automatically generating a decoder file.

FIG. 3 shows a flow chart of one embodiment of custom decoder operation.

FIG. 4 shows an embodiment of a message flow in a test and measurement system.

FIG. 5 shows an embodiment of a user interface.

### DETAILED DESCRIPTION

The embodiments disclosed herein provide users with the ability to build systems that can decode signals in the electrical layer to easily test devices transmitting and receiving the signals. Using AI based decoders (AID) as disclosed in the embodiments can reduce a user's workflow by 80% turnaround time. The embodiments also help users to customize protocol packets to their customer needs, such as confidential packets used in military and government applications. The embodiments allow users to quickly build protocol decodes with low code and no code models to ensure faster time to insights into the bus environment.

Generally, the embodiments herein comprise variations of a four-step process to acquire a complete decoder for use. The user uploads the specification to a generative AI model. The user also provides bus configuration boundaries and definitions through a user interface, typically provided by an Application Programming Interface (API) to the AI model. This allows the generative AI model to produce internal prompts related to developing the decoder protocol. The generative AI model then converts the specification and the bus configuration and boundaries into a Declarative Decoder Language (DDL) file for deployment. The user can then deploy the DDL file into the test and measurement instrument, such as an oscilloscope immediately.

Tektronix's Declarative Decoder Language (DDL) is a proprietary high-level scripting language designed to define custom protocol decoders for use within Tektronix test and measurement instruments, such as oscilloscopes and logic analyzers. It enables users to declaratively specify how waveform data is translated into protocol-level information by mapping signal transitions to symbols, defining protocol layers, and identifying trigger conditions based on specific data patterns or errors. DDL supports multi-layer decoding, error detection, and integration with visualization tools that correlate decoded data across waveform, character, and protocol views. This language facilitates real-time analysis, decoding, and triggering on complex serial protocols, enhancing the flexibility and diagnostic capabilities of Tektronix instruments.

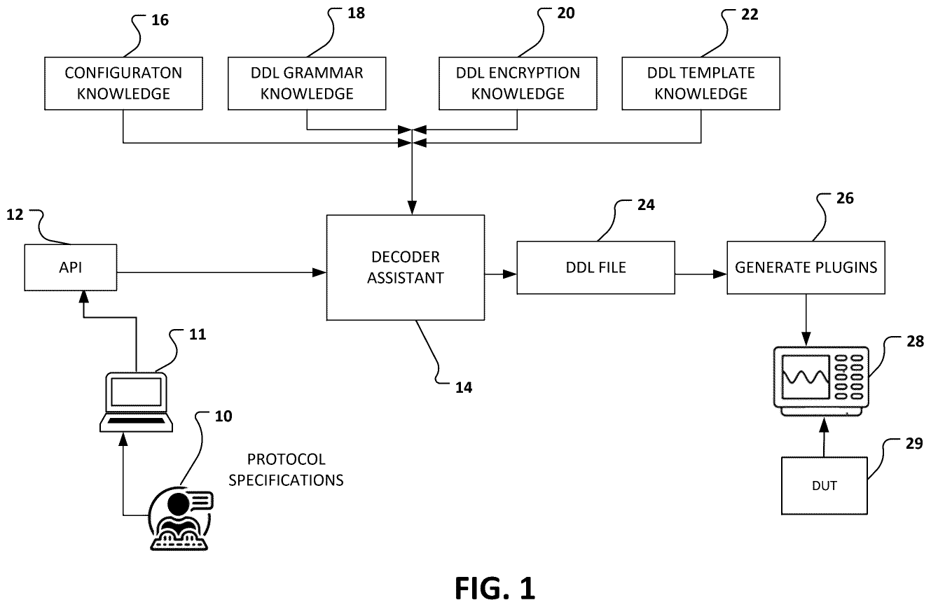

FIG. 1 shows an embodiment of a test and measurement system. User 10 uploads the protocol specification for the new protocol through the API 12 for the Decoder Assistant generative AI model 14. The embodiments herein refer to the generative AI model as a Decoder Assistant 14, not to be confused with the AI assistant with which the user interacts. The Decoder Assistant 14 has received configuration knowledge 16, DDL grammar knowledge 18, DDL encryption knowledge 20, and DDL template knowledge 22 through training. The model then takes the bus protocol and the bus configuration specifications and generates a DDL file 24. A computing device, such as 11 in FIG. 1, within the test and measurement system, receives the DDL file from Decoder Assistant 14 to run scripts that produce the plug-ins at 26. As the capabilities of test and measurement instruments continue to increase, the computing device and the test and measurement instrument 28 may comprise the same device. The computing device and the test and measurement instrument may include one or more processors that execute code to operate in the test and measurement system, including the generative AI model.

The test and measurement system then uses the DDL file to generate any necessary “plug-ins.” As used here, the term “plug-in” refers to a file that is automatically generated from the DDL file for use on the instrument that allow the instrument to use the DDL file and display results from the decode on the instrument. In one embodiment, these plug-ins comprise an extended markup language (XML) file and a Qt Meta-object Language (QML) file. Other types of plug-ins of course may be generated. Computing device 11 then receives the DDL file from the Decoder Assistant 14 and generates the necessary plug-ins. In one embodiment the plug-ins are generated by scripts executed by the computing device. Alternatively, in some embodiments, the Decoder Assistant may generate the plug-ins. Once the files are generated, they are deployed to the test and measurement instrument 28 that then can use them to debug busses operating under those protocols as devices under test. The DUT 29 may connect to the test and measurement instrument through a test fixture where the DUT connects to the test fixture to send packets in accordance with the bus protocol, which can then be decoded using the DDL file and/or plug-in files for the new protocol.

The example embodiment discussed above uses the specific examples of the Decoder Assistant generating a DDL file, as well as a computing device generating plug-ins from the generated DDL file. However, DDL is a Tektronix proprietary language, and the use of plug-ins as another software abstraction layer may be specific to Tektronix's implementation of supporting custom decoders. Embodiments of the disclosure are not limited to the generation or use of a DDL file, nor to the generation or use of plug-in files generated from that DDL file. Embodiments of the disclosure may also be used with other test and measurement instrument manufacturers' proprietary protocol decoding languages and/or decoding engine implementations. This disclosure may use the term “decoder file” generally and interchangeably to refer to a generated DDL file compatible with Tektronix test and measurement instruments, and/or a similar file that is compatible with other manufacturers' test and measurement instruments.

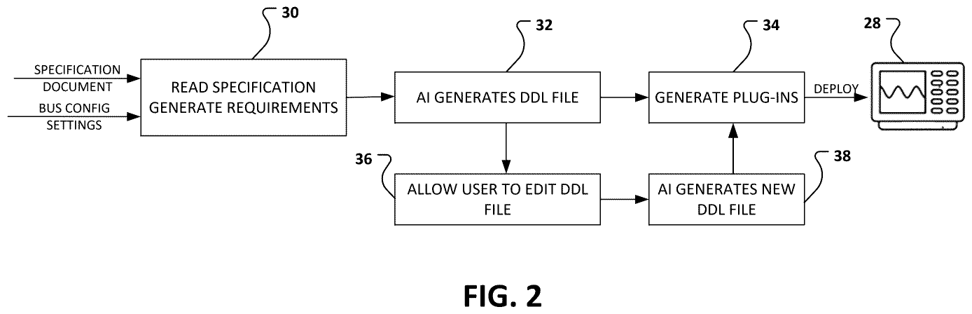

FIG. 2 shows an embodiment of a process for automatically generating a decoder file. At 30 the user assigns the protocol specification document to the Decoder Assistant for which custom decoder must be created. The user provides bus configuration settings, such as voltage thresholds that define the signals, inputs to the bus, baud rate if the bus may use multiple rates, etc. The Decoder Assistant extracts the protocol requirements from the specifications, which is then passed to Decoder assistant internally using system prompts. These internally generated prompts also pass the DDL grammar knowledge, and the DDL file template to create the DDL file at 32. As discussed below, the user may edit the DDL file as shown at 36. If the user does not edit the DDL file, the AI uses the generated DDL file at 32. The system then generates the plug-ins at 34 and an encrypted DDL file (EDDL) and the plug-ins are provided to the instrument at 28. The EDDL files allows management of secure features on Tektronix instruments to ensure no one tampers with the DDL file and enables features that are not authorized. The instrument, or an application running on the instrument 28, is relaunched to allow it to recognize and include the EDDL file and the plug-ins. If the user decides to edit the DDL file at 36, the Decoder Assistant (AI) then generates a new DDL file and its accompanying EDDL file at 38, and the process returns to 34.

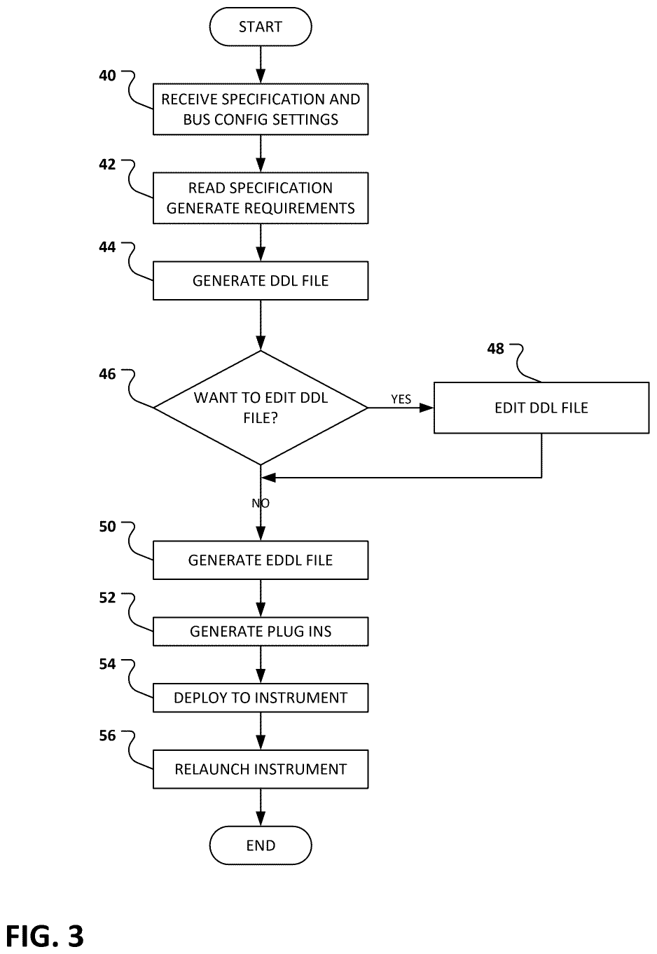

FIG. 3 shows a flow chart of one embodiment of custom decoder generation. At 40, the Decoder Assistant receives the specification and bus configuration settings from the user. The Decoder Assistant then “reads” the specification and generates the requirements to generate a DDL file at 42 and generates the DDL file at 44. The Decoder Assistant then offers the user the opportunity to review and/or edit the generated DLL file at 46. If the user just reviews the file, the system moves on with the generated DDL file and generates the encrypted DDL (EDDL) file at 50. If the user edits the DDL file at 48, a new DDL file is generated before the EDDL file is generated at 50. The plug-ins are generated at 52, and the EDDL file and the plug-ins are deployed to the instrument by putting them in a specified path for the instrument at 54. The instrument is then relaunched at 56, which may involve relaunching an application that manages the instrument, a reboot of the instrument, or some other type of updating that allows the instrument to access the new DDL file and plug-ins.

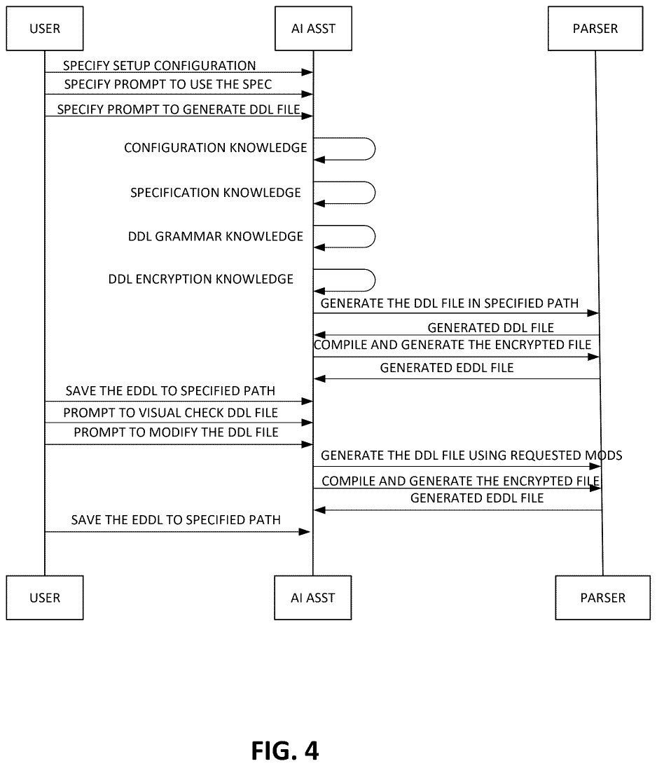

FIG. 4 shows an embodiment of a message flow in a test and measurement system. The user provides the setup configuration, the prompt to upload the specification, and the direction to generate a DDL file. The Decoder Assistant then uploads the configuration knowledge, the specification knowledge, DDL grammar knowledge, and the encryption knowledge. It uses the parser with the generative AI model to generate the DDL file in the specified path and then generates the EDDL file. The Decoder Assistant then interacts with the user to allow the user to check the file, and if there are changes, generates the new DDL file and the new EDDL file. The user then directs the EDDL file to be saved into the specified path.

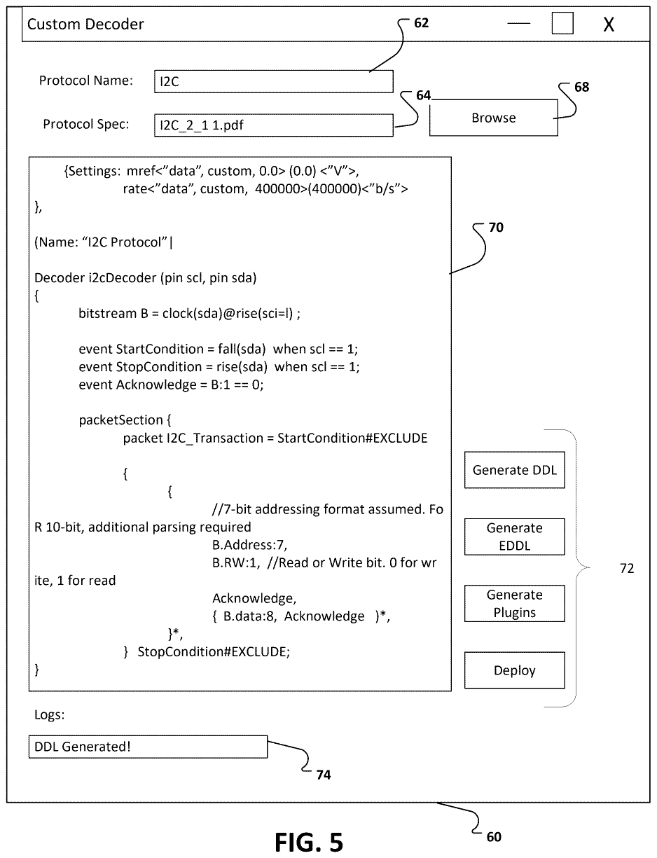

FIG. 5 shows an embodiment of a user editing interface 60 for the Decoder Assistant. The windows 62 and 64 allow the user to enter the protocol name, in this example I2C, and the specification, I2C_2_1 1.pdf. If the user needs to, they can browse to the protocol specification file at 68. Once the DDL file is generated, the Decoder Assistant displays it in editing window 70. Once it is completed, the user can select Generate DDL. When the status window 74 shows that the DDL file has been generated, the user can select Generate EDDL, and then the plug-ins and deploy to the instrument using buttons 72.

As mentioned above, the user prompts the Decoder Assistant to create the DDL file. The Decoder Assistant generates an internal prompt, an example of which is shown below.

| | |
|---|---|
| prompt = | f”Here is specification for {protocol_name} Protocol give as {spec} which has |
| | information the the “ \ |
| | f”protocol layer decoding with respect to all events its packet framing. With “ \ |
| | f”the syntax and info for a ddl language: {grammar}. Write me a ddl code similar to |

{ddl} for “ \

f”{protocol_name} protocol.”

In this manner a user can update instruments with new communication protocols as needed in a much simpler manner than previous approaches. Using the Decoder Assistant as set out in the embodiments above, users can generate decoders more quickly by communicating with natural language. The additional software that generates the needed plug-ins and deploys the plug-ins and EDDL files makes it easier for engineers to develop and create traction into the market. Learning for the tool/grammar is minimal because of the use of AI for part of the process.

Further, the existing solution for Tektronix® instruments is a proprietary tool (TLX) that can be used to develop serial bus protocols more quickly. However, as mentioned above, TLX does not support user-owned protocols. Users can have access to this tool so they can use their own proprietary protocol decode solutions when wanting to debug systems using Tektronix® equipment.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried out by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement system, comprising: one or more test and measurement instruments comprising at least one test and measurement instrument having one or more ports to connect the at least one test and measurement instrument to a device under test (DUT); one or more user interfaces; a generative artificial intelligence (AI) model connected to the one or more test and measurement instruments; and one or more processors configured to execute code that causes the one or more processors to: provide an application programming interface (API) of the generative AI model; receive a protocol specification for a protocol and provide the protocol specification to the generative AI model through the API; receive, through one of the one more user interfaces, configuration settings for a bus that operates in accordance with the protocol; provide the configuration settings to the generative AI model; receive a decoder file from the generative AI model; deploy the decoder file to the test and measurement instrument; and use the decoder file on the test and measurement instrument to test a DUT that includes a bus that operates in accordance with the protocol.

Example 2 is the test and measurement system of Example 1, further comprising a computing device, wherein one or more of the user interfaces and the one or more processors reside on the computing device.

Example 3 is the test and measurement system of either of Examples 1 or 2, wherein the one or more processors are further configured to execute code that causes the one or more processors to provide one of the one or more user interfaces and render the decoder file on one of the one or more user interfaces.

Example 4 is the test and measurement system of Example 3, wherein the one or more processors are further configured to execute code that causes the one or more processors to receive edits to the decoder file and generate a new decoder file with the edits.

Example 5 is the test and measurement system of any of Examples 1 through 4, wherein the one or more processors are further configured to execute code that causes the one or more processors to execute scripts to generate plug-ins for the test and measurement instrument.

Example 6 is the test and measurement system of Example 5, wherein the code that causes the one or more processors to deploy the decoder file to the test and measurement instrument comprises code that causes the one or more processors to load the decoder file and the plug-ins to the test and measurement instrument.

Example 7 is the test and measurement system of any of Examples 1 through 6, wherein the one or more processors are further configured to execute code that causes the one or more processors to train the generative AI model with information about the decoder.

Example 8 is the test and measurement system of Example 7, wherein the information about the decoder file includes one or more of configuration knowledge, decoder file grammar, decoder file encryption knowledge, and decoder file template knowledge.

Example 9 is the test and measurement system of any of Examples 1 through 8, wherein the one or more processors are further configured to execute code that causes the one or more processors to generate an encrypted decoder file from the decoder file received from the generative AI model.

Example 10 is a method, comprising: providing an application programming interface (API) to a generative AI model; receiving a protocol specification for a protocol and providing the protocol specification to the generative AI model through the API; receiving, through a user interface, configuration settings for a bus that operates in accordance with the protocol; providing the configuration settings to the generative AI model; receiving a decoder file from the generative AI model; deploying the decoder file to a test and measurement instrument; and using the decoder file on the test and measurement instrument to test a device under test (DUT) that includes a bus that operates in accordance with the protocol.

Example 11 is the method of Example 10, further comprising providing a user editing user interface and rendering the decoder file on the user interface.

Example 12 is the method Examples 11 further comprising receiving edits to the decoder file and generating a new decoder file with the edits.

Example 13 is the method of any of Examples 10 through 12, further comprising executing scripts to generate plug-ins for the test and measurement device.

Example 14 is the method of Example 13, wherein deploying the decoder file to the test and measurement instrument comprises loading the decoder file and the plug-ins to the test and measurement instrument.

Example 15 is the method of any of Examples 10 through 14, further comprising training the generative AI model with information about the decoder file.

Example 16 is the method of Example 15, wherein the information about the decoder file includes one or more of configuration knowledge, decoder file grammar, decoder file encryption knowledge, and decoder file template knowledge.

Example 17 is the method of any of Examples 10 through 16, further comprising generating an encrypted decoder file from the decoder file received from the generative AI model.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement system, comprising:
one or more test and measurement instruments comprising at least one test and measurement instrument having one or more ports to connect the at least one test and measurement instrument to a device under test (DUT);
one or more user interfaces;
a generative artificial intelligence (AI) model connected to the one or more test and measurement instruments; and
one or more processors configured to execute code that causes the one or more processors to:
provide an application programming interface (API) of the generative AI model;
receive a protocol specification for a protocol and provide the protocol specification to the generative AI model through the API;
receive, through one of the one more user interfaces, configuration settings for a bus that operates in accordance with the protocol;
provide the configuration settings to the generative AI model;
receive a decoder file from the generative AI model;
deploy the decoder file to the test and measurement instrument; and
use the decoder file on the test and measurement instrument to test a DUT that includes a bus that operates in accordance with the protocol.

2. The test and measurement system as claimed in claim 1, further comprising a computing device, wherein one or more of the user interfaces and the one or more processors reside on the computing device.

3. The test and measurement system as claimed in claim 1, wherein the one or more processors are further configured to execute code that causes the one or more processors to provide an editing user interface as one of the one or more user interfaces and render the decoder file on the editing user interface.

4. The test and measurement system as claimed in claim 3, wherein the one or more processors are further configured to execute code that causes the one or more processors to receive edits to the decoder file and generate a new decoder file with the edits.

5. The test and measurement system as claimed in claim 1, wherein the one or more processors are further configured to execute code that causes the one or more processors to execute scripts to generate plug-ins for the test and measurement instrument.

6. The test and measurement system as claimed in claim 5, wherein the code that causes the one or more processors to deploy the decoder file to the test and measurement instrument comprises code that causes the one or more processors to load the decoder file and the plug-ins to the test and measurement instrument.

7. The test and measurement system as claimed in claim 1, wherein the one or more processors are further configured to execute code that causes the one or more processors to train the generative AI model with information about the decoder file.

8. The test and measurement system as claimed in claim 7, wherein the information about the decoder file includes one or more of configuration knowledge, decoder file grammar, decoder file encryption knowledge, and decoder file template knowledge.

9. The test and measurement system as claimed in claim 1, wherein the one or more processors are further configured to execute code that causes the one or more processors to generate an encrypted decoder file from the decoder file received from the generative AI model.

10. A method, comprising:
providing an application programming interface (API) to a generative AI model;
receiving a protocol specification for a protocol and providing the protocol specification to the generative AI model through the API;
receiving, through a user interface, configuration settings for a bus that operates in accordance with the protocol;
providing the configuration settings to the generative AI model;
receiving a decoder file from the generative AI model;
deploying the decoder file to a test and measurement instrument; and
using the decoder file on the test and measurement instrument to test a device under test (DUT) that includes a bus that operates in accordance with the protocol.

11. The method as claimed in claim 10, further comprising providing a user editing user interface and rendering the decoder file on the user editing user interface.

12. The method as claimed in claim 11, further comprising receiving edits to the decoder file and generating a new decoder file with the edits.

13. The method as claimed in claim 10, further comprising executing scripts to generate plug-ins for the test and measurement device.

14. The method as claimed in claim 13, wherein deploying the decoder file to the test and measurement instrument comprises loading the decoder file and the plug-ins to the test and measurement instrument.

15. The method as claimed in claim 10, further comprising training the generative AI model with information about the decoder file.

16. The method as claimed in claim 15, wherein the information about the decoder file includes one or more of configuration knowledge, decoder file grammar, decoder file encryption knowledge, and decoder file template knowledge.

17. The method as claimed in claim 10, further comprising generating an encrypted decoder file from the decoder file received from the generative AI model.
